(19) United States
(12) Patent Application Publication
(10) Pub. No.: US 2007/0010042 A1
(43) Pub. Date: Jan. 11, 2007

(54) METHOD OF MANUFACTURING A CMOS IMAGE SENSOR

(76) Inventor: Sheng-Chin Li, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/160,658

(22) Filed: Jul. 5, 2005

(51) Int. Cl. H01L 31/113; H01L 31/062; H01L 21/00

(52) U.S. Cl. 438/70

(57) ABSTRACT

The present invention relates to the method of manufacturing an image sensor, the method comprising providing a semiconductor substrate, which comprises a pixel array area and a logic area, a plurality of the photodiodes are formed on the semiconductor substrate of the pixel array area, a multilevel interconnect process is processed on the semiconductor substrate, a passivation is doping on the pixel array area and the logic area, removing the passivation on the pixel array area, and a plurality of the color filter arrays are formed on the pixel array area and correspond to the photodiode individually.

### BACKGROUND OF THE INVENTION

1. Field of the Invention

The present invention relates to a method of manufacturing an image sensor, more particularly to, a method of manufacturing a CMOS image sensor.

2. Description of the Prior Art

The CMOS image sensor applies in digital electrical products recent years. For example, the line CMOS image sensor majors the scanner and the plane CMOS majors the digital camera. Because the standard CMOS manufacture and the recent semiconductor equipment and technology could manufacture the CMOS image sensor, the yield of the CMOS image sensor becomes greater.

Please refer to FIG. 1, FIG. 1 is a schematic diagram of manufacturing the CMOS image sensor 140 forms on the semiconductor substrate 100 according to the prior art. The semiconductor substrate 100 comprises a plurality of shallow trench isolations 120 and a plurality of photodiodes 122 which electrically contacts at least a correspondingly CMOS (not shown). The shallow trench isolation 120 is the insulator between the photodiode 122 and the adjacent photodiode 122 and the photodiode 122 will not contact with other components and will not be short.

In the prior art, the flat layer 102 covers the photodiode 122 on the semiconductor substrate 100, the metal layer 124 and the dielectric layer 104 form on the flat layer 102, then, the metal layer 126 and the dielectric layer 106 form on dielectric layer 104. The metal layer 124 and the metal layer 126 formed on the area over the shallow trench isolation, that causes the shooting incident light (not shown) gathers in the photodiode 122 without scattering and cross talk. The mental layer 124, 126 are the multilevel interconnects for CMOS electrically contact. Later, the passivation 108 and the silicon nitride are formed for preventing the mist gets in the components.

Finally, the plurality of color filter arrays 128 are formed on the silicon nitride. The red, green and blue color pattern composes the color filter arrays and forms over the individual photodiode 122. The color filter arrays 128 are covered by the spacer layer 112 and the spacer layer 112 is concealed by the acrylate material polymer layer (not shown). The exposure, photolithography and reflow process proceed to form the plurality of U-lens 134 on the polymer layer. In the long run, the CMOS image sensor accomplishes.

As we know the prior CMOS image sensor has low resolution and cross talk noise. The manufacturers want to increase the ratio of the width of the photodiode divides the height of the color filter array to the semiconductor substrate, to increase the resolution of the image sensor. The important issue of the subject is how to increase the ratio of the width of the photodiode divides the height of the color filter array to the semiconductor substrate.

### SUMMARY OF THE INVENTION

The present invention relates to a method of manufacturing an image sensor to solve the above-mention problems.

The embodiment of the present invention relates to the method of manufacturing an image sensor, the method comprising providing a semiconductor substrate, which comprises a pixel array area and a logic area, a plurality of the photodiodes are formed on the semiconductor substrate of the pixel array area, a multilevel interconnect process is processed on the semiconductor substrate, a passivation is doping on the pixel array area and the logic area, removing the passivation on the pixel array area, and a plurality of the color filter arrays are formed on the pixel array area and correspond to the photodiode individually.

The present invention has no passivation on the pixel array area I, so the ratio of the width of the photodiode divides the height of the color filter array to the semiconductor substrate increases and the resolution increases too.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of forming the CIS on the semiconductor substrate according to the prior art.

FIGS. 2 to 7 are the schematic diagrams of forming the CIS on the semiconductor substrate according to the present invention.

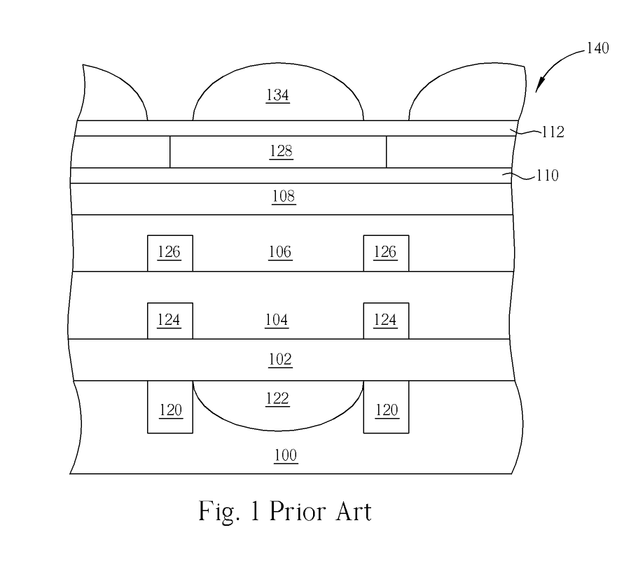

### DETAILED DESCRIPTION

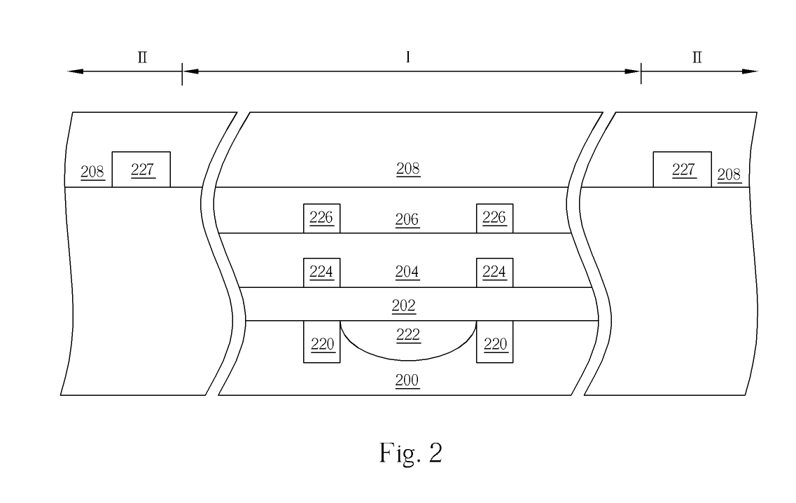

Please refer to FIG. 2 to 7, FIG. 2 to 7 are the schematic diagram of manufacturing the CMOS image sensor forms on the semiconductor substrate according to the present invention. As FIG. 2 shows, the semiconductor substrate 200 divides into the pixel array area I and the logic area II. In the pixel array area I, the semiconductor substrate 200 comprises the plurality of shallow trench isolations 220 and the plurality of photodiodes 222. Each of the photodiode 222 contacts electrically with the correspondingly CMOS (not shown). The shallow trench isolation 220 uses as the insulator of the photodiode 222 and the adjacent photodiode 222, that prevents the short circuit from the photodiode 222 contacts the other components.

In the present invention, the flat layer 202 is formed on the semiconductor substrate 200 to cover the photodiode 222 and CMOS (not shown), the plurality of metal layers 224 and the dielectric layer 204 are formed on the flat layer 202, then, the plurality of metal layers 226 and the dielectric layer 206 are formed on dielectric layer 204. The metal layer 224 and the metal layer 226 are formed on the area over the shallow trench isolation, that causes the shooting incident light (not shown) gathers in the photodiode 222 without scattering and cross talk. The mental layer 224, 226 are the multilevel interconnects for CMOS electrically contact, and are formed by the metal sputter, the etching or copper process.

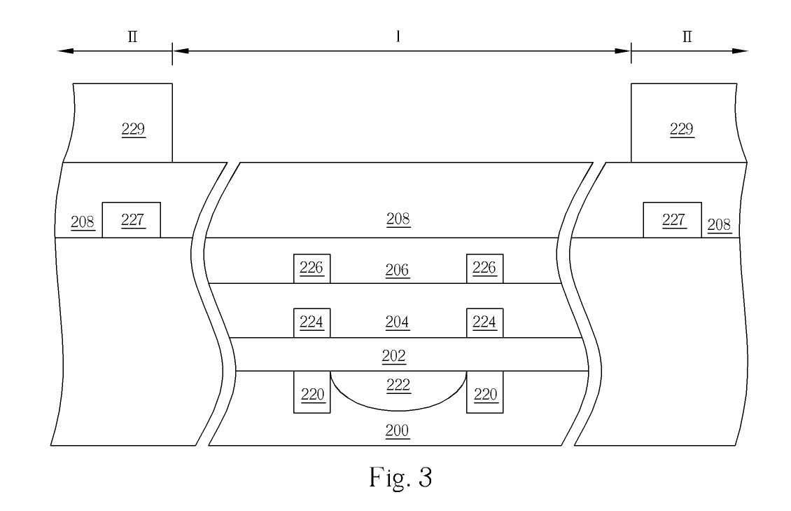

Next, a mental layer 227 is formed on the dielectric layer 206 of the logic area II uses as the foreign connect wire of CIS to complete the multilevel interconnects. Then, the passivation 208 is doped on the semiconductor substrate 200, the material of passivation is selected form silica or phosphosilicate, and so on. The photoresist layer (not shown) is forming on the passivation 208 by the spin coating and the photo mask (not shown) defines the pixel array area I and the logic area II. For example, when the photoresist is a positive photoresist, the pixel array area I will be shot in the exposure and the logic area II won't. As FIG. 3 shown, the developer penetrates into the photoresist layer (not shown) to form the mask on the logic area II.

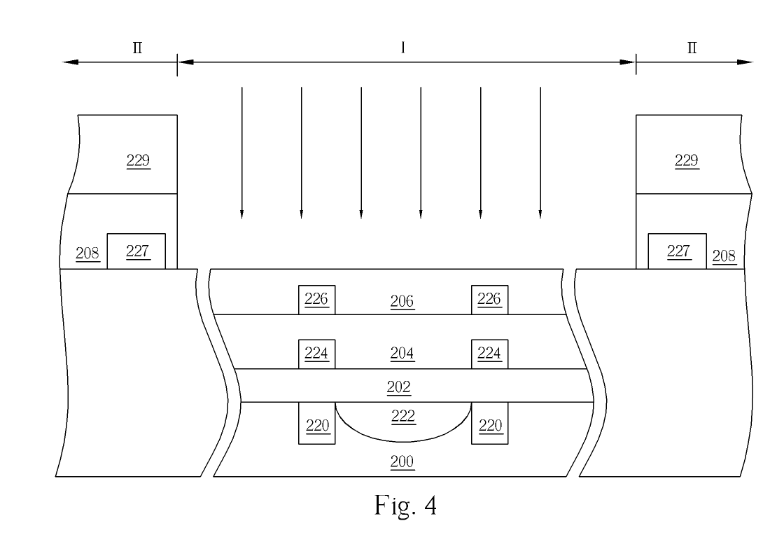

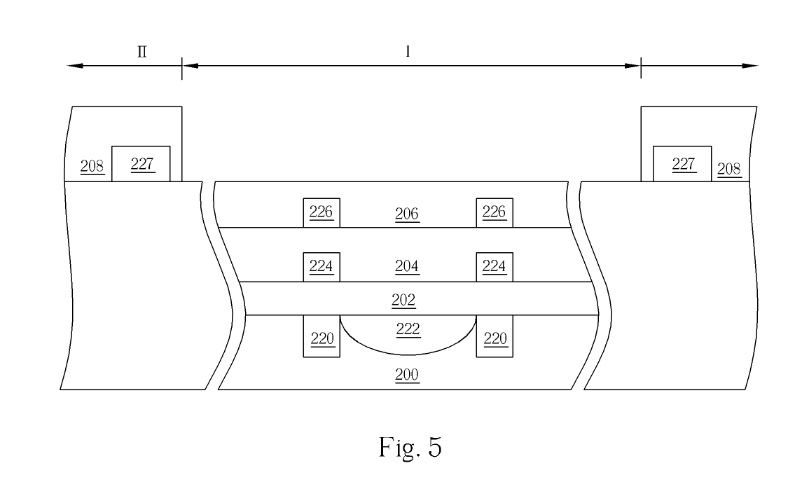

Please refer to FIG. 4, the etching process is processed on the semiconductor substrate 200. Because the pixel array area I has no mask 229, the passivation 208 of the pixel array area I will be etched and the passivation 208 of the pixel array area II will be reserved for the mask 229 covering. The photolithogragh process is finished and the mask 229 is striped as FIG. 5 shown. It is worth to pay attention, the pixel array area I has no passivatin 208 but the logic area II has, that's means when the metal layer 227 on the logic area II need to protect, the present invention could doped the dielectric layer (not shown) on the semiconductor substrate 200 to protect the mental layer 227 according to the product structure, the design requirement and the reality purpose.

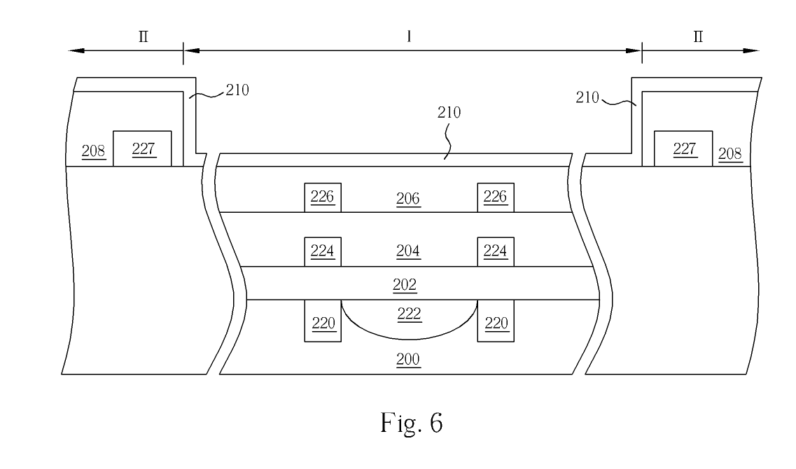

Please refer to FIG. 6, the silicon nitride 210 is doped on the semiconductor substrate 200 for preventing the mist gets in the multilevel interconnects and the components, then, the pattern photoresist layer (not shown) is formed on the logic area II and processes the etching process to form a pad open reaches the metal layer 227 of the logic area II.

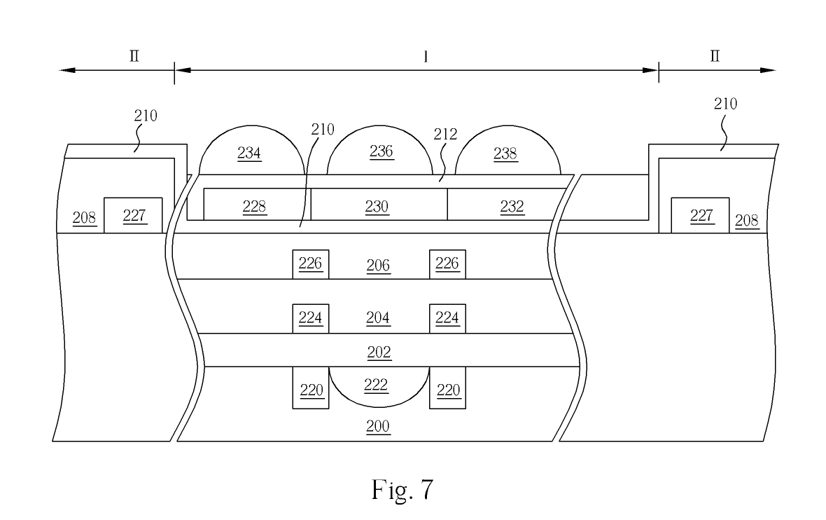

As FIG. 7 shown, the silicon nitride 210 is formed the red 228, green 230 and blue color filter arrays 232 on the correspondingly photodiode 222, then, the spacer layer 212 is formed on the color filter arrays 228, 230 and 232, and the polymer layer (not shown) made form the acrylate material is formed on the spacer layer 121. Finally, the exposure, development and reflow process is proceeded for forming the U-lens 234,236 and 268 on the correspondingly color filter arrays 228, 230 and 232 and the CIS completes.

Comparing to the prior art, the CIS according to the present invention has no passivation 208 on the pixel array area I, so the ratio of the width of the photodiode 222 divides the height of the color filter array 228, 230, 232 to the photodiode 222 increases and the resolution increase too. In the prior art, the height of the passivation 108 to the semiconductor substrate 100 is 34 k to 85 k, but the dielectric layer 206 to the semiconductor substrate 200 is 26 k. The present invention solves the problems of the prior art, mends the cross talk noise and improves the resolution.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. The method of manufacturing an image sensor, the method comprising:
providing a semiconductor substrate, which comprises a pixel array area and a logic area;
a plurality of the photodiodes are formed on the semiconductor substrate of the pixel array area;
a multilevel interconnect process is processed on the semiconductor substrate;
a passivation is doping on the pixel array area and the logic area;
removing the passivation on the pixel array area; and
a plurality of the color filter arrays are formed on the pixel array area and correspond to the photodiode individually.

2. The method of claim 1, wherein the image sensor is a CMOS image sensor (CIS) and each photodiode electrically contacts to at least one CMOS.

3. The method of claim 1, wherein the pixel array area further comprises a plurality of insulators between the photodiode and the adjacent photodiode.

4. The method of claim 3, wherein the multilevel interconnect at least comprises:
forming a first dielectric layer and a plurality of first metal layers of the semiconductor substrate surface and the first metal layers are in the first dielectric layer; and
forming a second dielectric layer and a plurality of second metal layers of the first dielectric layer and the second metal layers are in the second dielectric layer.

5. The method of claim 4, wherein the first metal layers and the second metal layers on the pixel array area are sequentially stacked between the photodiode and the adjacent photodiode, and on the insulator.

6. The method of claim 4, wherein the multilevel interconnect further comprises a step of forming a plurality of the third metal layers in the logic area and on the second dielectric layer surface.

7. The method of claim 4, wherein the passivation formed on the second dielectric layer surface and made from an oxide layer.

8. The method of claim 7, wherein the method further comprises forming a silicon nitride layer on the second dielectric layer surface of the pixel array area and the passivation surface of the logic area for resisting mist.

9. The method of claim 8, wherein the color filter array is formed on the silicon nitride surface.

10. The method of claim 1, wherein the method further comprises forming a plurality of U-lens set on the corresponding color filter array surface.

11. The method of claim 10, wherein the method comprises a spacer layer is formed between the U-lens and the color filter array.

12. The structure of an image sensor comprising:
a semiconductor substrate, which comprises a pixel array area and a logic area;
a plurality of photodiodes are formed on the pixel array area of the semiconductor substrate;
at least one dielectric layer has a metal layer on the semiconductor substrate;
a passivation is only formed on the dielectric layer of the logic area; and
a plurality of color filter arrays on the dielectric layer of the pixel area, wherein the color filter arrays are corresponding with the photodiodes.

13. The substrate of claim 12, wherein the structure of an image sensor further comprises a plurality of insulators are formed on the pixel array area of the semiconductor substrate, the photodiode is formed between the insulator and the adjacent insulator, the metal layer of the dielectric layer is formed on the insulator.

14. The substrate of claim 12, wherein the image sensor is a CMOS image sensor (CIS) and each photodiode electrically contacts to at least one CMOS.

15. The substrate of claim 12, wherein the passivation made from an oxide layer.

16. The substrate of claim 12, wherein the substrate further comprises a silicon nitride layer is on the dielectric layer surface of the pixel array area and the passivation surface of the logic area for resisting mist.

17. The method of claim 16, wherein the color filter array is formed on the silicon nitride surface.

18. The method of claim 17, wherein the structure further comprises a plurality of U-lens set on the corresponding color filter array surface.

19. The method of claim 18, wherein the structure comprises a spacer layer is formed between the U-lens and the color filter array.
